(19) United States
(12) Patent Application Publication
(10) Pub. No.: US 2008/0090310 A1
(43) Pub. Date: Apr. 17, 2008

(54) SUBSTRATE PROCESSING APPARATUS AND SUBSTRATE PROCESSING TERMINATION DETECTION METHOD

(75) Inventor: Susumu SAITO, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/854,102

(22) Filed: Sep. 12, 2007

Related U.S. Application Data
(60) Provisional application No. 60/870,794, filed on Dec. 19, 2006.

(30) Foreign Application Priority Data
Oct. 13, 2006 (JP) 2006-280461

(51) Int. Cl. H01L 21/66; C23C 16/00

(52) U.S. Cl. 438/9; 118/712; 257/E21.528

(57) ABSTRACT

A substrate processing apparatus capable of completely removing an oxide layer that can cause defects in electronic devices, without lowering throughput of the apparatus. A process ship of the substrate processing apparatus includes a process module in which COR processing is performed on a wafer and another process module in which PHT processing is performed on a wafer. The latter process module includes a process module exhaust system through which volatile gases and other gases in a chamber are exhausted. This exhaust system includes an analysis unit communicated with a main exhaust pipe between the chamber and an APC valve and adapted to measure concentrations of the volatile gases in the exhausted gases and detect a termination of the PHT processing.

### BACKGROUND OF THE INVENTION

1. Field of the Invention

The present invention relates to a substrate processing apparatus and a substrate processing termination detection method, and more particularly, to a substrate processing apparatus for removing an oxide layer and a termination detection method for use in the substrate processing apparatus.

2. Description of the Related Art

A method for fabricating electronic devices from a silicon wafer (hereinafter referred to as the “wafer”) is known that includes steps of film formation, lithography, and etching. In the film formation step, a conductive film or an insulating film is formed on a surface of the wafer using CVD (chemical vapor deposition) or the like. The lithography step forms a photoresist layer in a desired pattern on the conductive film or the insulating film. The etching step forms the conductive film into gate electrodes or forms wiring grooves or contact holes in the insulating film, using plasma produced from a processing gas and using the photoresist layer as a mask.

In some electronic device fabrication method, a polysilicon layer formed on a wafer is etched. In this case, trenches (grooves) are formed in the wafer, and a deposit film of a SiO₂ layer is formed on side surfaces of the trenches.

The SiO₂ layer causes problems for the electronic devices such as conduction failures, and hence must be removed. As a SiO₂ layer removal method, there is known a substrate processing method that subjects the wafer to COR (chemical oxide removal) processing and PHT (post heat treatment) processing. The COR processing causes a chemical reaction between the SiO₂ layer and gas molecules to produce a product. The PHT processing heats the wafer having been subjected to the COR processing, to vaporize and sublimate the product produced on the wafer in the COR processing, thereby removing the product from the wafer.

To implement such a substrate processing method, there is known a substrate processing apparatus having a chemical reaction processing apparatus and a heat treatment apparatus connected thereto. The chemical reaction processing apparatus has a chamber and carries out the COR processing on a wafer housed in the chamber. The heat treatment apparatus has a chamber and carries out the PHT processing on a wafer housed therein (see, for example, U.S. Laid-open Patent Publication No. 2004/0185670).

With this substrate processing apparatus, however, if the PHT processing is insufficiently performed in the heat treatment apparatus, a product cannot completely be removed from a wafer, posing a problem that an unremoved product remaining on the wafer can produce defective electronic devices formed on the wafer.

On the other hand, if a time period of the PHT processing is set to be excessively long in order to completely remove the product from the wafer, there is a problem of remarkably reducing throughput of the substrate processing apparatus.

### SUMMARY OF THE INVENTION

The present invention provides a substrate processing apparatus and a substrate processing termination detection method capable of completely removing, without reducing throughput of the apparatus, an oxide layer that can produce defects in electronic devices formed on a substrate.

According to a first aspect of the present invention, there is provided a substrate processing apparatus for processing a substrate having a surface thereof formed with an oxide layer, comprising a chemical reaction processing apparatus adapted to cause a chemical reaction of the oxide layer with gas molecules to thereby produce a product on the surface of the substrate, and a heat treatment apparatus adapted to heat the substrate on the surface of which the product has been produced, wherein the heat treatment apparatus includes a generated gas analysis apparatus adapted to analyze gases generated from the heated substrate.

According to the substrate processing apparatus of this invention, a substrate formed on its surface with a product through a chemical reaction between the oxide layer and gas molecules is heated, and gases generated from the heated substrate are analyzed. The product is vaporized and sublimated by being heated. When the product has completely been vaporized and sublimated thereby having been removed from the substrate, the gases are stopped from being generated. By analyzing the generated gases, a termination at which the product has completely been removed can be detected. As a result, a time period for which the substrate is heated can be set appropriately, whereby the oxide layer that can produce defects in electronic devices formed on the substrate can completely be removed, while improving the throughput of the apparatus.

The heat treatment apparatus can include a housing chamber in which the substrate is housed and a gas exhaust system that exhausts gases in the housing chamber, and the generated gas analysis apparatus can be disposed in the gas exhaust system.

In that case, the generated gas analysis apparatus is disposed in the gas exhaust system that exhausts gases in the housing chamber, making it possible to isolate the generated gas analysis apparatus from inside the housing chamber. As a result, processing performed in the generated gas analysis apparatus never affects on processing performed in the housing chamber.

The generated gas analysis apparatus can include a gas introduction chamber into which the gases exhausted from the housing chamber are taken in, a plasma generation apparatus adapted to generate plasma in the gas introduction chamber, and a spectroscopic measurement apparatus adapted to spectrally disperse emissions from atoms or molecules in the gases excited by the plasma and measure dispersed light intensities.

In that case, a plasma for exciting atoms or molecules in the generated gases is generated, emissions from atoms or molecules in the generated gases excited by the plasma are spectrally dispersed, and dispersed light intensities are measured. From the measured dispersed light intensities, the concentrations of atoms or molecules can be measured.

The generated gas analysis apparatus can include an exhaust pipe through which the gases in the housing chamber are exhausted, a plasma generation apparatus adapted to generate plasma in the exhaust pipe, and a spectroscopic measurement apparatus adapted to spectrally disperse emissions from atoms or molecules in the gases excited by the plasma and measure dispersed light intensities.

In that case, since the plasma is generated in the exhaust pipe that exhausts gases, necessity of the provision of a gas introduction chamber for taking in gases is eliminated, thus making it possible to perform gas analysis with a low-priced construction.

The generated gas analysis apparatus can include an exhaust pipe through which the gases in the housing chamber are exhausted, a plasma generation apparatus adapted to generate plasma in the exhaust pipe, and a spectroscopic measurement apparatus adapted to spectrally disperse an afterglow observed downstream of a central part of plasma generation in the exhaust pipe and measure dispersed light intensities.

In that case, afterglow observed downstream of a central part of plasma generation in the exhaust pipe is spectrally dispersed, and dispersed light intensities are measured. From the measured dispersed light intensities, it is possible to accurately measure the concentrations of atoms or molecules in the generated gases.

The generated gas analysis apparatus can include a mass analyzer.

In that case, the gas analysis can be performed more precisely using the mass analyzer.

The generated gas analysis apparatus can include a Fourier transform infrared spectrophotometer.

In that case, the gas analysis can be performed further precisely using the Fourier transform infrared spectrophotometer.

The heat treatment apparatus can include a housing chamber in which the substrate is housed, and the generated gas analysis apparatus can be disposed in the housing chamber.

In that case, since the generated gas analysis apparatus is disposed in the housing chamber, the generated gas analysis apparatus can easily take in gases in the housing chamber, making it possible to reliably carry out the gas analysis.

The generated gas analysis apparatus can include a gas introduction chamber into which the gases exhausted from the housing chamber are taken in, a plasma generation apparatus adapted to generate plasma in the gas introduction chamber, and a spectroscopic measurement apparatus adapted to spectrally disperse emissions from atoms or molecules in the gases excited by the plasma and measure dispersed light intensities.

In that case, from the measured dispersed light intensities, the concentrations of atoms or molecules in the generated gases can be measured.

The generated gas can include at least one of silicon fluoride gas, ammonia gas, hydrogen fluoride gas, nitrogen gas, and hydrogen gas.

In that case, the generated gas includes at least one of silicon tetrafluoride gas, ammonia gas, hydrogen fluoride gas, nitrogen gas, and hydrogen gas. Thus, emissions from atoms or molecules in the generated gas are ensured, making it possible to reliably measure the dispersed light intensities, whereby the gas analysis can be carried out with reliability.

The chemical reaction processing apparatus can include a second housing chamber in which the substrate is housed, an ammonia gas supply system adapted to supply ammonia gas into the second housing chamber, a hydrogen fluoride gas supply system adapted to supply hydrogen fluoride gas into the second housing chamber, and a supplied gas analysis apparatus adapted to analyze at least one of the ammonia gas and the hydrogen fluoride gas supplied into the second housing chamber.

In that case, at least one of ammonia gas and hydrogen fluoride gas supplied to the second housing chamber is analyzed. The analysis on the supplied gas or gases makes it possible to confirm whether the apparatus normally operates.

The chemical reaction processing apparatus can include a second housing chamber in which the substrate is housed, a hydrogen fluoride gas supply system adapted to supply hydrogen fluoride gas into the second housing chamber, and a supplied gas analysis apparatus adapted to analyze the hydrogen fluoride gas supplied to the second housing chamber.

In that case, the hydrogen fluoride gas supplied to the second housing chamber is analyzed. The analysis on the supplied gas makes it possible to confirm whether the apparatus normally operates.

The chemical reaction processing apparatus can include a supplied gas exhaust system adapted to exhaust the gas supplied into the second housing chamber, and the supplied gas analysis apparatus can be disposed in the supplied gas exhaust system.

In that case, since the supplied gas analysis apparatus is disposed in the supplied gas exhaust system for exhausting the gas in the second housing chamber, it is possible to isolate the supplied gas analysis apparatus from inside the second housing chamber. Thus, processing performed in the supplied gas analysis apparatus never affects on processing performed in the second housing chamber.

The supplied gas analysis apparatus can include a second gas introduction chamber adapted to take in the gas exhausted from the second housing chamber, a second plasma generation apparatus adapted to generate plasma in the second gas introduction chamber, and a second spectroscopic measurement apparatus adapted to spectrally disperse emissions from atoms or molecules in the gases excited by the plasma and measure dispersed light intensities.

In that case, plasma that excites atoms or molecules in the supplied gases is generated, emissions from atoms or molecules in the supplied gases excited by the plasma are spectrally dispersed, and dispersed light intensities are measured. From the measured intensities, the concentrations of atoms or molecules in the supplied gases can be measured.

The supplied gas analysis apparatus can include a second exhaust pipe adapted to exhaust the gas in the second housing chamber, a second plasma generation apparatus adapted to generate plasma in the second exhaust pipe, and a second spectroscopic measurement apparatus adapted to spectrally disperse emissions from atoms or molecules in the gases excited by the plasma and measure dispersed light intensities.

In that case, plasma is generated in the second exhaust pipe from which the gases in the second housing chamber are exhausted, making it unnecessary to provide a second gas introduction chamber for taking in the gases. As a result, the gas analysis can be performed with a low-priced construction.

The supplied gas analysis apparatus can be disposed in the second housing chamber.

In that case, since the supplied gas analysis apparatus is disposed in the second housing chamber, the supplied gas analysis apparatus can easily taken in the gas in the second housing chamber, making it possible to perform the gas analysis with reliability.

The supplied gas analysis apparatus can include a second gas introduction chamber adapted to take in the gases in the second housing chamber, a second plasma generation apparatus adapted to generate plasma in the second gas introduction chamber, and a second spectroscopic measurement apparatus adapted to spectrally disperse emissions from atoms or molecules in the gases excited by the plasma and measure dispersed light intensities.

In that case, plasma for exciting atoms or molecules in the supplied gases is generated, emissions from the atoms or molecules in the supplied gases excited by the plasma are spectrally dispersed, and dispersed light intensities are measured. From the measured dispersed light intensities, concentrations of the atoms or molecules in the supplied gases can be measured.

According to a second aspect of the present invention, there is provided a substrate processing termination detection method for use in a substrate processing apparatus for processing a substrate having a surface thereof formed with an oxide layer, comprising a chemical reaction processing step of causing a chemical reaction of the oxide layer with gas molecules to thereby produce a product on the surface of the substrate, and a heat treatment step of heating the substrate on the surface of which the product has been produced, wherein the heat treatment step includes a generated gas analysis step of analyzing gases generated from the heated substrate.

With the termination detection method of this invention, it is possible to completely remove an oxide layer which can cause defects in electronic devices and improve the throughput of a substrate processing apparatus, as in the substrate processing apparatus according to the present invention.

The generated gas analysis step includes a plasma generation step of generating a plasma for exciting atoms or molecules in the generated gases, and a spectroscopic measurement step of spectrally dispersing emissions from atoms or molecules in the gases excited by the plasma and measuring dispersed light intensities.

In that case, from the measured dispersed light intensities, the concentrations of atoms or molecules in the generated gases can be measured.

The generated gas analysis step can include a plasma generation step of generating a plasma for exciting atoms or molecules in the generated gases in an exhaust pipe through which the generated gases are exhausted, and a spectroscopic measurement step of spectrally dispersing emissions from atoms or molecules in the gases excited by the plasma and measuring dispersed light intensities.

In that case, gas analysis can be performed with a low-priced construction.

The generated gas analysis step can include a plasma generation step of generating a plasma for exciting atoms or molecules in the generated gases in an exhaust pipe through which the generated gases are exhausted, and a spectroscopic measurement step of spectrally dispersing emissions from an afterglow observed downstream of a central part of plasma generation in the exhaust pipe and measuring dispersed light intensities.

In that case, from the measured dispersed light intensities, the concentrations of the atoms or molecules in the generated gases can be measured with accuracy.

Further features of the present invention will become apparent from the following description of an exemplary embodiment with reference to the attached drawings.

### BRIEF DESCRIPTION OF THE DRAWINGS

FIG. 1 is a plan view schematically showing the construction of a substrate processing apparatus according to an embodiment of the present invention;

FIG. 2A is a sectional view of a second process module taken along line II-II in FIG. 1;

FIG. 2B is an enlarged view of a portion A shown in FIG. 2A;

FIG. 3 is a sectional view of a third process module appearing in FIG. 1;

FIG. 4 is a perspective view schematically showing the construction of a second process ship shown in FIG. 1;

FIG. 5A is a schematic view showing the construction of an analysis unit shown in FIG. 4;

FIG. 5B is a schematic view showing a modification of the analysis unit shown in FIG. 5A;

FIG. 6A is a view for explaining a modified COR processing executed by the substrate processing apparatus;

FIG. 6B shows a modified PHT processing; and

FIG. 7 is a plan view schematically showing the construction of a substrate processing apparatus according to a modification of the embodiment.

### DETAILED DESCRIPTION OF THE PREFERRED EMBODIMENT

The present invention will now be described in detail below with reference to the drawings showing a preferred embodiment thereof.

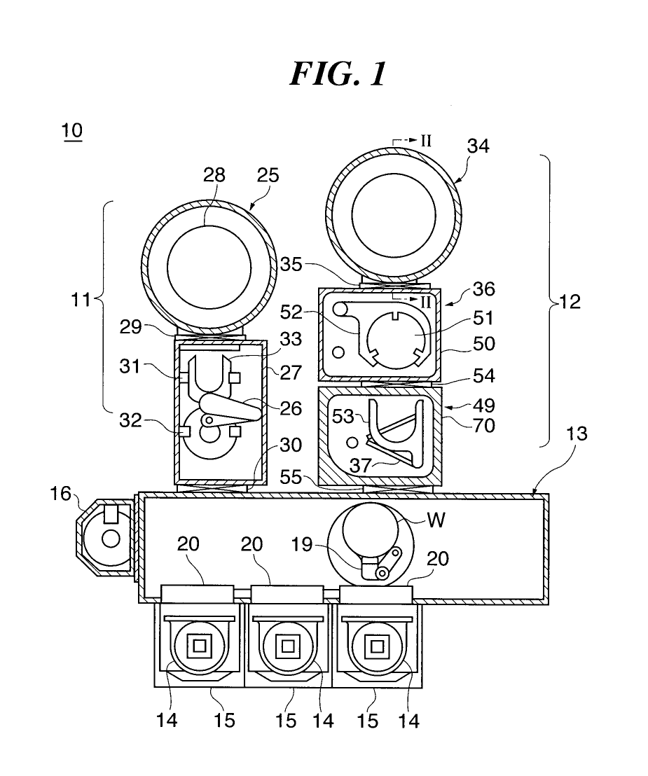

As shown in FIG. 1, the substrate processing apparatus 10 has a first process ship 11 for carrying out reactive ion etching (RIE) on electronic device wafers W (hereinafter referred to “wafers W”), a second process ship 12 disposed parallel to the first process ship 11 for carrying out the below-mentioned COR (chemical oxide removal) processing and PHT (post heat treatment) processing on the wafers W, and a loader module 13 which is a rectangular common transfer chamber connected with the process ships 11, 12.

In addition to the process ships 11 and 12, three FOUP mounting stages 15 each mounted with a FOUP (front opening unified pod) 14, which is a container for housing twenty-five wafers W, are connected to the loader module 13. There is also connected to the loader module 13 an orienter 16 that carries out pre-alignment of the position of each wafer W transferred out from a FOUP 14.

The first and second process ships 11, 12 are connected to a longitudinal side wall of the loader module 13 and disposed facing the three FOUP mounting stages 15 with the loader module 13 therebetween. The orienter 16 is disposed at one longitudinal end of the loader module 13.

The loader module 13 includes a SCARA-type dual arm transfer arm mechanism 19 disposed therein and adapted to transfer the wafers W, and three loading ports 20 disposed in a side wall of the loader module 13 in correspondence with the FOUP mounting stages 15 and permitting the wafers W to be introduced therethrough into the loader module 13. The transfer arm mechanism 19 takes a wafer W out from a FOUP 14 mounted on a FOUP mounting stage 15 through the corresponding loading port 20, and transfers the removed wafer W into and out of the first process ship 11, the second process ship 12, and the orienter 16.

The first process ship 11 has a first process module 25 in which etching is carried out on a wafer W, and a first load lock module 27 containing a link-type single pick first transfer arm 26 for transferring a wafer W into and out of the first process module 25.

The first process module 25 has a cylindrical processing chamber, and upper and lower electrodes disposed in the chamber. The distance between the upper and lower electrodes is set to an appropriate value for carrying out the RIE processing on wafers W. The lower electrode has in a top portion thereof an ESC (electrostatic chuck) 28 for chucking a wafer W thereto using a Coulomb force or the like.

In the first process module 25, a processing gas is introduced into the chamber and an electric field is generated between the upper and lower electrodes, whereby the introduced processing gas is turned into plasma to produce ions and radicals by which the RIE processing is performed on each wafer W.

In the first process ship 11, the internal pressure of the first process module 25 is held at vacuum, whereas the internal pressure of the loader module 13 is held at atmospheric pressure. To this end, a vacuum gate valve 29 is provided at a connecting part between the first load lock module 27 and the first process module 25, and an atmospheric gate valve 30 is provided at a connecting part between the first load lock module 27 and the loader module 13. The first load lock module 27 is constructed as a preliminary vacuum transfer chamber having an adjustable internal pressure.

Within the first load lock module 27, the first transfer arm 26 is disposed in an approximately central portion of the module 27, first buffers 31 are disposed toward the first process module 25 with respect to the first transfer arm 26, and second buffers 32 are disposed toward the loader module 13 with respect to the first transfer arm 26. The buffers 31, 32 are disposed on a track along which a support portion (pick) 33 moves, the support portion 33 being disposed at a distal end of the first transfer arm 26 and being for supporting a wafer W. A wafer W subjected to the RIE processing is temporarily laid by above the track of the support portion 33, whereby swapping over of the wafer W subjected to the RIE processing and a wafer W to be subjected to the RIE processing can be carried out smoothly in the first process module 25.

The second process ship 12 has a second process module 34 (chemical reaction processing apparatus) in which COR processing is carried out on a wafer W, a third process module 36 (heat treatment apparatus) that is connected to the second process module 34 via a vacuum gate valve 35 and in which PHT processing is carried out on a wafer W, and a second load lock module 49 containing a link-type single pick second transfer arm 37 for transferring a wafer W into and out of the second and third process modules 34, 36.

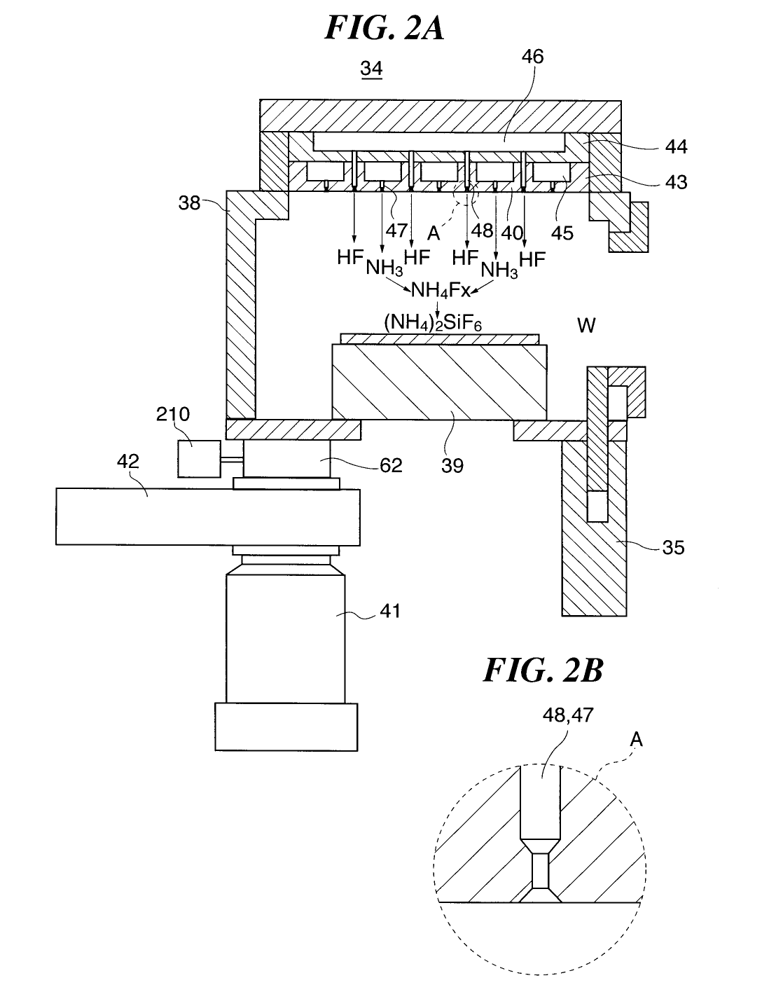

FIG. 2A is a sectional view of the second process module 34 taken along line II-II in FIG. 1, and FIG. 2B is an enlarged view of a portion A shown in FIG. 2A.

As shown in FIG. 2A, the second process module 34 has a cylindrical processing chamber 38, a wafer stage 39 disposed in the chamber 38 and adapted to be mounted with a wafer W, a shower head 40 disposed above the chamber 38, a TMP (turbo molecular pump) 41 for exhausting gas out from the chamber 38, and an APC (adaptive pressure control) valve 42 that is a variable butterfly valve disposed between the chamber 38 and the TMP 41 for controlling the pressure in the chamber 38.

The wafer stage 39 has a coolant chamber (not shown) as a temperature adjusting mechanism. A coolant, for example, cooling water or a Galden fluid, at a predetermined temperature is circulated through the coolant chamber. A processing temperature of the wafer W placed on an upper surface of the wafer stage 39 is controlled through the coolant temperature. It is preferable that the wafer stage 39 be maintained within a range from 10 to 30 degrees C.

The wafer stage 39 has pusher pins (not shown) as lifting pins adapted to project out from the upper surface of the wafer stage 39. The pusher pins are housed inside the wafer stage 39 when a wafer W is placed on the wafer stage 39, and are made to project out from the upper surface of the wafer stage 39 to lift the wafer W up when the wafer W subjected to the COR processing is to be transferred out from the chamber 38. It should be noted that in this embodiment an ESC may be employed instead of the wafer stage 39.

The shower head 40 has a two-layer structure comprised of lower and upper layer portions 43, 44 having first and second buffer chambers 45, 46 communicated with the interior of the chamber 38 via gas-passing holes 47, 48. That is, the shower head 40 is comprised of two plate-shaped members (the layer portions 43, 44) disposed one upon another and formed with internal channels through which gases supplied into the first and second buffer chambers 45, 46 flow into the chamber 38.

When carrying out the COR processing on wafers W, NH₃ (ammonia) gas is supplied into the first buffer chambers 45 from an ammonia gas supply pipe 57 described below, and the supplied ammonia gas is then supplied via the gas-passing holes 47 into the chamber 38. Moreover, HF (hydrogen fluoride) gas is supplied into the second buffer chamber 46 from a hydrogen fluoride gas supply pipe 58 described below, and the supplied hydrogen fluoride gas is then supplied via the gas-passing holes 48 into the chamber 38.

By the way, the COR processing is processing for causing a chemical reaction of an oxide layer on the wafer W with gas molecules to thereby produce a product.

In this embodiment, ammonia gas and hydrogen fluoride gas are employed for the COR processing. It should be noted that argon gas may be added. Hydrogen fluoride gas promotes corrosion of the SiO₂ layer. Ammonia gas synthesizes by-products that restrict a chemical reaction between the oxide layer (SiO₂ layer) and hydrogen fluoride gas, where required, and finally terminate the chemical reaction. It is preferable that a greater amount of ammonia gas than the supply amount of hydrogen fluoride gas should be supplied. For example, the ratio of flow rate (sccm) of ammonia gas to that of hydrogen fluoride gas preferably varies in a range from 1:1 to 2:1. It is also preferable that the partial pressure of a mixture of ammonia gas and hydrogen fluoride gas in the chamber 38 be set in a range from 10 to 40 mTorr. More specifically, this embodiment utilizes the following chemical reactions in the COR processing.

SiO₂+4HF→SiF₄+2H₂O↑

SiF₄+2NH₃+2HF→(NH₄)2SiF₆

In this embodiment, the pressure in the chamber 38 is maintained to be equal to or less than 1 Torr.

The shower head 40 has a heater (not shown), for example, a heating element built therein. The heating element is preferably disposed on the upper layer portion 44 for controlling the temperature of the hydrogen fluoride gas in the second buffer chamber 46.

As shown in FIG. 2B, each of the gas-passing holes 47, 48 has a portion thereof opening out into the chamber 38 and formed so as to widen out toward an end thereof, whereby the ammonia gas and the hydrogen fluoride gas can be made to diffuse through the chamber 38 efficiently. Furthermore, each of the gas-passing holes 47, 48 has a cross-sectional shape having a constriction therein, whereby any deposit produced in the chamber 38 can be prevented from flowing back into the gas-passing holes 47, 48 and thus into the first and second buffer chambers 45, 46. Alternatively, the gas-passing holes 47, 48 may be formed into a spiral shape.

The second process module 34 for carrying out the COR processing on wafers W adjusts the pressure in the chamber 38 and the flow rate ratio between ammonia gas and hydrogen fluoride gas, as described above.

The second process module 34 is designed such that the ammonia gas and the hydrogen fluoride gas are mixed together for the first time in the chamber 38 (post-mixing design), and hence the two gases are prevented from mixing together until they are introduced into the chamber 38, whereby the hydrogen fluoride gas and the ammonia gas are prevented from reacting with each another before being introduced into the chamber 38.

In the second process module 34, a heater (not shown), for example a heating element, is built into a side wall of the chamber 38. As a result, the temperature of the atmosphere in the chamber 38 can be prevented from decreasing, thereby improving the reproducibility of the COR processing. Moreover, the heating element in the side wall controls the temperature of the side wall, whereby by-products formed in the chamber 38 can be prevented from becoming attached to the inside of the side wall.

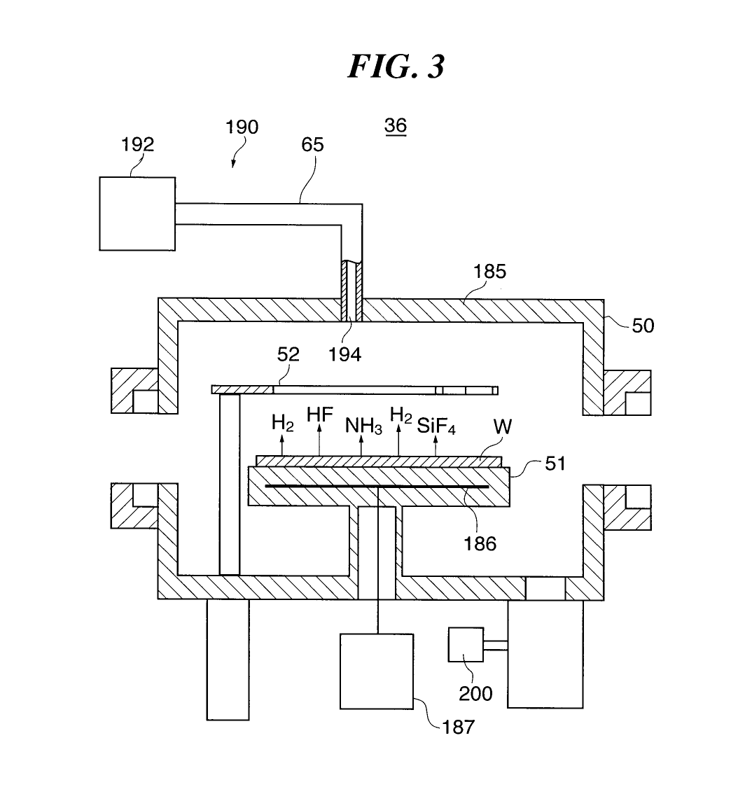

FIG. 3 is a sectional view of the third process module 36 appearing in FIG. 1.

As shown in FIG. 3, the third process module 36 has a box-shaped processing chamber 50, a stage heater 51 adapted to be mounted with a wafer W and disposed in the chamber 50 such as to face a ceiling portion 185 of the chamber 50, a buffer arm 52 disposed in the vicinity of the stage heater 51 for lifting up a wafer W mounted on the stage heater 51, and a PHT chamber lid (not shown) disposed in the ceiling portion 185 of the chamber 50 and functioning as an openable/closable lid for shielding the interior of the chamber 50 from the outside ambient.

The stage heater 51 is made of aluminum formed on its surface with an oxide film, and heats a wafer W mounted thereon to a predetermined temperature using a heater 186 comprised of a built-in heating wire or the like. Specifically, the stage heater 51 directly heats a wafer W mounted thereon up to 100 to 200 degrees C., preferably approximately 135 degrees C. A heating amount of the heater 186 is controlled by a heater controller 187.

A sheet heater of silicon rubber disposed in the PHT chamber lid heats the wafer W from above. Moreover, an outer periphery of the chamber 50 is covered by a heat shield (not shown).

Instead of the sheet heater, a UV radiation heater may be provided in the ceiling portion 185, as a heater for heating the wafer W from above. An example of a UV radiation heater is a UV lamp that emits UV of wavelength 190 to 400 nm.

The buffer arm 52 temporarily retracts a wafer W having been subjected to the COR processing to a position upward of a track of the support portion 53 of the second transfer arm 37, whereby swapping over of wafers W in the second and third process modules 34, 36 can be carried out smoothly.

In the third process module 36, the PHT processing is carried out on wafers W by adjusting the temperature of the wafers W.

The PHT processing is a processing in which a wafer W having been subjected to the COR processing is heated to thereby vaporize and sublimate a product produced on the wafer W due to a chemical reaction in the COR processing, thus removing the product from the wafer W. More specifically, this embodiment utilizes the following chemical reaction in the PHT processing.

(NH₄)2SiF₆→SiF_{4↑}+2NH_{3↑}+2HF↑

It should be noted that in the PHT processing, slight amounts of N₂ and H₂ are also generated as shown in FIG. 3.

The third process module 36 includes a nitrogen gas supply system 190.

The nitrogen gas supply system 190 includes a nitrogen gas supply unit 192 and a nitrogen gas supply pipe 65 connected to the unit 192. The supply pipe 65 has a nitrogen gas supply hole 194 that opens at the ceiling portion 185 of the chamber 50 so as to face a wafer W mounted on the stage heater 51. The supply unit 192 supplies, as a purge gas, nitrogen (N₂) gas from the supply hole 194 via the supply pipe 65, thereby discharging gases generated (vaporized) in the PHT processing. In addition, the supply unit 192 adjusts the flow rate of the nitrogen gas to be supplied. Specifically, it is preferable that the flow rate of nitrogen gas be set in a range from 500 to 3000 sccm, for example.

Referring to FIG. 1 again, the second load lock module 49 has a box-shaped transfer chamber 70 containing the second transfer arm 37. The internal pressure of each of the second and third process modules 34, 36 is held at vacuum or a pressure below atmosphere pressure, whereas the internal pressure of the loader module 13 is held at atmospheric pressure. To this end, a vacuum gate valve 54 is provided in a connecting part between the second load lock module 49 and the third process module 36, and an atmospheric door valve 55 is provided in a connecting part between the second load lock module 49 and the loader module 13. The second load lock module 49 is constructed as a preliminary vacuum transfer chamber having an adjustable internal pressure.

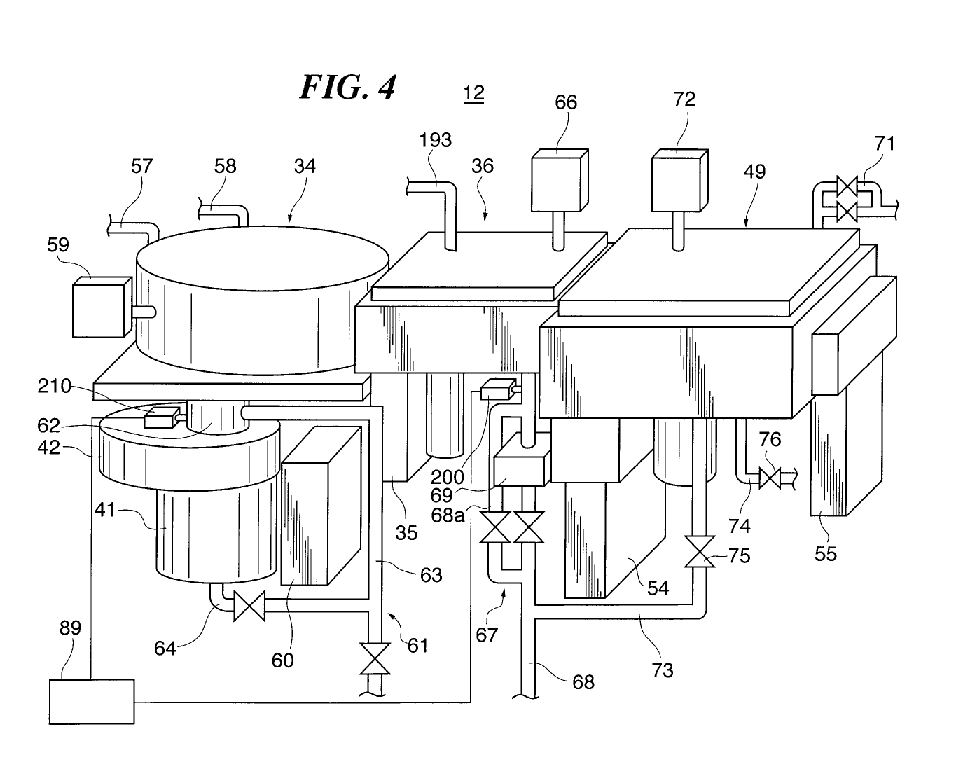

FIG. 4 is a perspective view schematically showing the construction of the second process ship 12 appearing in FIG. 1.

As shown in FIG. 4, the second process module 34 has the ammonia gas supply pipe 57 for supplying ammonia gas into the first buffer chambers 45, the hydrogen fluoride gas supply pipe 58 for supplying hydrogen fluoride gas into the second buffer chamber 46, a pressure gauge 59 for measuring the pressure in the chamber 38, and a chiller unit 60 for supplying a coolant into the cooling system provided in the wafer stage 39.

The ammonia gas supply pipe 57 has provided therein an MFC (mass flow controller), not shown, for adjusting the flow rate of the ammonia gas supplied into the first buffer chambers 45, and the hydrogen fluoride gas supply pipe 58 has provided therein an MFC (not shown) for adjusting the flow rate of the hydrogen fluoride gas supplied into the second buffer chamber 46. The MFCs in the pipes 57, 58 cooperate together to adjust the flow rate ratio between the ammonia gas and the hydrogen fluoride gas supplied into the chamber 38.

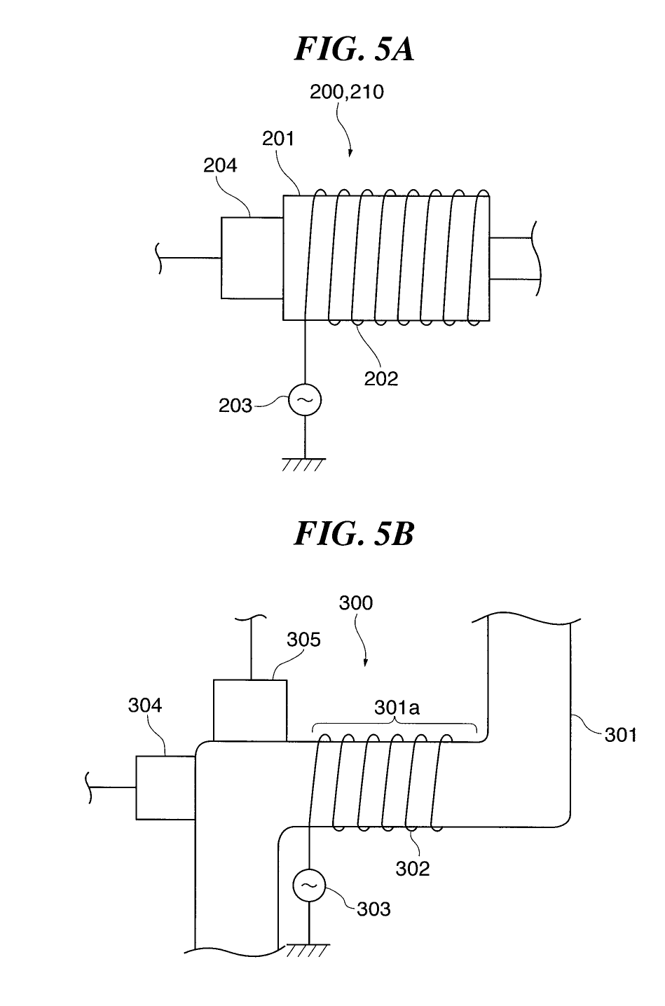

A second process module exhaust system 61 for exhausting gas out from the chamber 38 and analyzing the exhausted gas is disposed below the second process module 34 and connected to a DP (dry pump), not shown. The exhaust system 61 has an exhaust pipe 63 communicated with an exhaust duct 62 provided between the chamber 38 and the APC valve 42, an analysis unit 210 (a supplied gas analysis apparatus) communicated with the exhaust duct 62 and described later with reference to FIG. 5A, and an exhaust pipe 64 connected to a lower part (i.e. on the exhaust side) of the TMP 41. The exhaust pipe 64 is connected to the exhaust pipe 63 on the side upstream of the DP. The analysis unit 210 is connected to a system controller 89 for controlling operations of the first process ship 11, the second process ship 12, and the loader module 13.

The third process module 36 has the nitrogen gas supply pipe 65 through which nitrogen (N₂) gas is supplied to the chamber 50, a pressure gauge 66 for measuring the pressure in the chamber 50, and a third process module exhaust system 67 which is for exhausting nitrogen gas and the like out from the chamber 50 and for analyzing the nitrogen gas and the like exhausted from the chamber 50.

The nitrogen gas supply pipe 65 includes an MFC (not shown) for adjusting the flow rate of nitrogen supplied to the chamber 50. The third process module exhaust system 67 has a main exhaust pipe 68 communicated with the chamber 50 and connected to the DP, an APC valve 69 disposed part way along the main exhaust pipe 68, an analysis unit 200 (a generated gas analysis apparatus) described later with reference to FIG. 5A and communicated with the main exhaust pipe 68 between the chamber 50 and the APC valve 69, and an auxiliary exhaust pipe 68a branching off from the main exhaust pipe 68 so as to circumvent the APC valve 69 and connected to the main exhaust pipe 68 upstream of the DP. The APC valve 69 controls the pressure in the chamber 50. The analysis unit 200 is connected with the system controller 89, as with the analysis unit 210.

The second load lock module 49 has a nitrogen gas supply pipe 71 for supplying nitrogen gas into the chamber 70, a pressure gauge 72 for measuring the pressure in the chamber 70, a second load lock module exhaust system 73 for exhausting the nitrogen gas out from the chamber 70, and an atmosphere communicating pipe 74 for releasing the interior of the chamber 70 to the atmosphere.

The nitrogen gas supply pipe 71 has provided therein an MFC (not shown) for adjusting the flow rate of the nitrogen gas supplied into the chamber 70. The second load lock module exhaust system 73 is comprised of a single exhaust pipe communicated with the chamber 70 and connected to the main exhaust pipe 68 of the third process module exhaust system 67 upstream of the DP. Moreover, the second load lock module exhaust system 73 has an openable/closable exhaust valve 75 therein, and the external atmosphere communicating pipe 74 has an openable/closable relief valve 76 therein. These valves 75 and 76 cooperate together to adjust the pressure in the chamber 70 to any pressure from atmospheric pressure to a desired degree of vacuum.

FIG. 5A is a schematic view showing the constructions of the analysis units 200, 210 appearing in FIG. 4.

As shown in FIG. 5A, each of the analysis units 200, 210 includes a chamber 201 (gas introduction chamber) for taking-in gases exhausted from the chamber 50 or 38, a coil 202 wound around the chamber 201, a high-frequency power supply 203 (plasma generation apparatus) for causing a high-frequency current to flow through the coil 202 in order to generate plasma in the chamber 201, and an emission analyzer 204 (spectroscopic measurement apparatus) for spectrally dispersing emissions from atoms or molecules in the gases excited by the plasma and for measuring dispersed light intensities. The analysis units 200, 210 are capable of measuring the concentrations of atoms or molecules in the gases by measuring the light intensities using the emission analyzer 204. It should be noted that argon gas for plasma generation is supplied from a gas supply apparatus (not shown) to the chamber 201.

As described above, the PHT processing is carried out on a wafer W in the chamber 50 of the third process module 36. In the PHT processing, a product formed on the wafer W due to a chemical reaction in the COR processing is vaporized and sublimated. Specifically, volatile gases are generated from the wafer W such as silicon tetrafluoride gas, ammonia gas, hydrogen fluoride gas, nitrogen gas, and hydrogen gas. To exhaust the volatile gases, nitrogen gas is supplied as purge gas into the chamber 50 of the third process module 36. The third process module exhaust system 67 discharges gases including the volatile gases from inside the chamber 50.

In this embodiment, the concentrations of the volatile gases contained in the exhausted gases are measured using the analysis unit 200. In the PHT processing, when the product has completely been vaporized and sublimated, the volatile gases are stopped from being generated. Accordingly, a termination of the PHT processing can be detected by monitoring the concentrations of the volatile gases in the exhaust gases using the analysis unit 200. This makes it possible to appropriately set the time period of the PHT processing in the substrate processing, whereby a product which is a cause of defective electronic devices can completely be removed and the throughput of the apparatus can be improved. Since the analysis unit 200 is provided in the third process module exhaust system 67, the analysis unit 200 can be isolated from inside the chamber 50 of the third process module 36, and therefore, the processing performed in the analysis unit 200 never affects on the processing performed in the chamber 50.

On the other hand, the COR processing is performed on a wafer W in the chamber 38 of the second process module 34, as described above. In the COR processing, reactive gases such as ammonia gas and hydrogen fluoride gas are supplied to the chamber 38. In the second process module 34, the gases inside the chamber 38 are exhausted in order to maintain the pressure in the chamber 38 at a predetermined pressure. To this end, the second process module exhaust system 61 discharges gases including the reactive gases from inside the chamber 38.

In this embodiment, the concentrations of the reactive gases contained in the exhaust gases are measured using the analysis unit 210. By monitoring the concentrations of the reactive gases using the analysis unit 210, it is possible to confirm whether or not the apparatus operates normally.

In this embodiment, the analysis units are provided in the exhaust systems of respective ones of the process modules. However, these analysis units may be provided in the processing chambers. In that case, each analysis unit can easily take in gases within the housing chamber and can perform a reliable gas analysis. It should be noted that the processing in the analysis units never affects the processing in the processing chambers. Each analysis unit may be disposed at an arbitrary location in the exhaust system or in the processing chamber.

The provision of the analysis unit 210 is arbitrary. No analysis unit 210 may be provided in a case where it is unnecessary to confirm the status of operation of the second process module 34.

FIG. 5B is a schematic view showing the construction of a modification of the analysis unit 200 shown in FIG. 5A.

Referring to FIG. 5B, an analysis unit 300 includes a curved exhaust pipe 301 (part of the auxiliary exhaust pipe 68a) for discharging gases from inside the chamber 50, a coil 302 wound around the curved exhaust pipe 301, a high-frequency power supply 303 for causing a high-frequency current to flow through the coil 302 in order to generate plasma inside the curved exhaust pipe 301, and an emission analyzer 304 for spectrally dispersing emissions from atoms or molecules in the gases excited by the plasma and for measuring dispersed light intensities. The analysis unit 300 is capable of measuring the concentrations of atoms or molecules in the gases by measuring the light intensities using the emission analyzer 304. It should be noted that argon gas for plasma generation is supplied from a gas supply apparatus (not shown) to the curved exhaust pipe 301.

Also in this modification, the concentrations of volatile gases contained in the exhaust gases are measured using the analysis unit 300, and the termination of the PHT processing can be detected by monitoring the concentrations of the volatile gases in the exhaust gases using the analysis unit 300. Thus, also in this modification, it is possible to appropriately set the time period of the PHT processing in the substrate processing. Unlike the analysis unit 200, the provision of a chamber 201 is unnecessary, and therefore, advantages similar to the above-described advantages can be attained with a low-priced construction.

As shown in FIG. 5B, the analysis unit 300 may be provided with an afterglow analyzer 305 for spectrally dispersing an afterglow observed downstream of a central part 301a of plasma generation in the curved exhaust pipe 301 and for measuring the dispersed light intensities. Based on the light intensity measurement by the afterglow analyzer 305, the analysis unit 300 can accurately measure the concentrations of atoms or molecules in the gases. In that case, advantages similar to the above described advantages can be attained with reliability.

In the above described embodiment, the analysis unit is provided in order to measure the concentrations of volatile gases or reactive gases in exhaust gases, and the concentrations of the gases are measured by plasma emission analysis in the analysis unit. However, this is not limitative. For example, other than the plasma emission analysis, the analysis unit may perform a gas concentration measurement using a mass analyzer or a Fourier transform infrared spectrophotometer. In the case of using a mass analyzer, the gas analysis can be carried out more precisely. Using a Fourier transform infrared spectrophotometer, the gas analysis can be carried out further precisely.

Next, modified COR processing and PHT processing performed in the substrate processing apparatus according to the embodiment will be described.

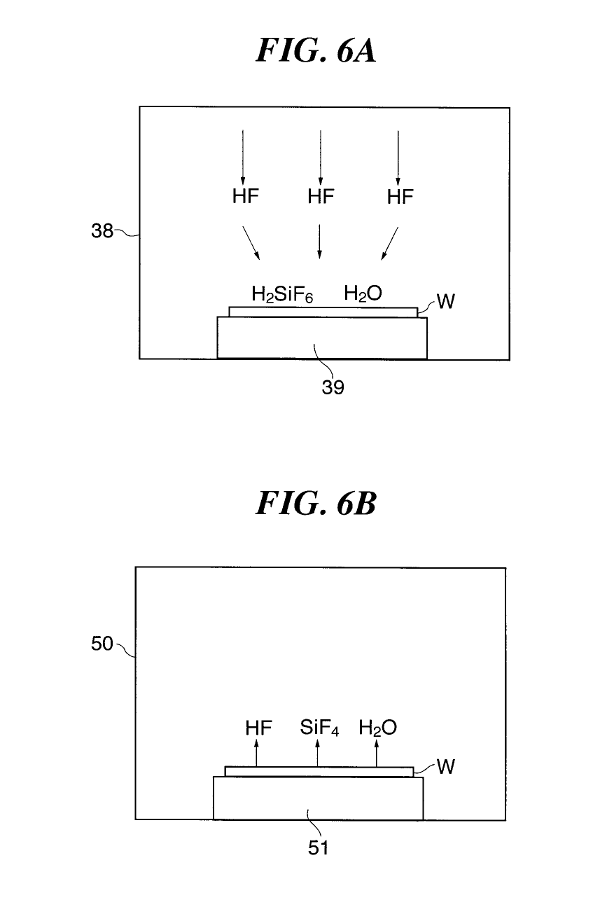

In an electronic device fabrication method, a polysilicon layer is etched using a hard mask formed into a predetermined pattern on a wafer in some cases. At this time, a deposit film comprised of a SiOBr layer is formed on side surfaces of trenches (grooves) formed by the etching. The SiOBr layer is a pseudo-SiO₂ layer, which is similar in property to a SiO₂ layer. From the viewpoint of improving throughput of the apparatus, it is preferable that the deposit film and the hard mask formed on the wafer be simultaneously removed. Since the hard mask can be removed using hydrogen fluoride, a single hydrogen fluoride gas is preferably used for the COR processing on wafers W. To this end, in this modification, as shown in FIG. 6A, the COR processing is performed on a wafer W while supplying hydrogen fluoride gas alone into the chamber 38 of the second process module 34, and as shown in FIG. 6B, the PHT processing is performed on a wafer W within the chamber 50 of the third process module 36, thereby simultaneously removing the deposit film and the hard mask. Specifically, in the COR processing and the PHT processing of this modification, the following chemical reactions are utilized.

SiO₂+6HF→H₂SiF₆+2H₂O (in the COR processing)

H₂SiF₆→SiF_{4↑}+2HF↑ (in the PHT processing)

H₂O→H₂O↑ (in the PHT processing)

In this modification, the pressures in the chambers 38, 50 are maintained at a high pressure less than 30 Torr. Preferably, the wafer stage 39 is maintained at a temperature in a rage from 10 to 40 degrees C., and the stage heater 51 directly heats a wafer W placed thereon up to 175 to 200 degrees C.

Also in this modification, advantages similar to the above described advantages can be realized by the provision of the analysis units described above.

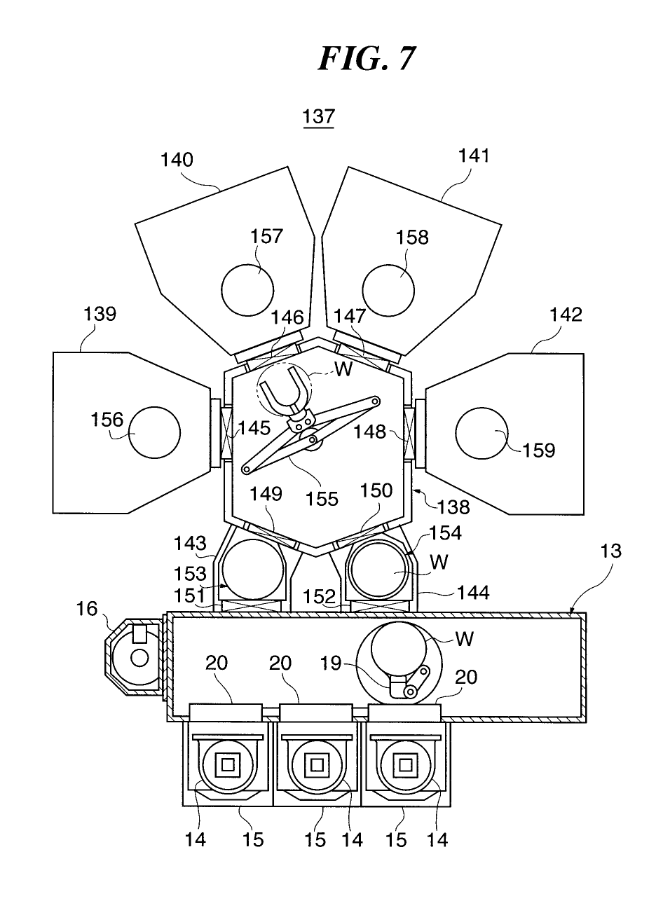

The substrate processing apparatus according to the above described embodiment is not limited to being a substrate processing apparatus of a parallel type having two process ships arranged in parallel with each other as shown in FIG. 1, but rather as shown in FIG. 7, the substrate processing apparatus may be one having a plurality of process modules radially arranged as vacuum processing chambers in which predetermined processing is carried out on the wafers W.

FIG. 7 is a plan view schematically showing the construction of the substrate processing apparatus according to a modification of the above described embodiment. In FIG. 7, component elements which are the same as or similar to ones of the substrate processing apparatus 10 in FIG. 1 are denoted by the same reference numerals as in FIG. 1, and description thereof is omitted here.

As shown in FIG. 7, the substrate processing apparatus 137 is comprised of a transfer module 138 having a hexagonal shape as viewed in plan, four process modules 139 to 142 arranged radially around the transfer module 138, a loader module 13, and two load lock modules 143, 144 each disposed between the transfer module 138 and the loader module 13 so as to couple the modules 138, 13 together.

The internal pressures of the transfer module 138 and each of the process modules 139 to 142 are held at vacuum. The transfer module 138 is connected to the process modules 139 to 142 by vacuum gate valves 145 to 148 respectively.

In the substrate processing apparatus 137, the internal pressure of the transfer module 138 is held at vacuum, whereas the internal pressure of the loader module 13 is held at atmospheric pressure. To this end, vacuum gate valves 149, 150 are provided in connecting parts between the load lock modules 143, 144 and the transfer module 138, and atmospheric door valves 151, 152 are provided in connecting parts between the load lock modules 143, 144 and the loader module 13, whereby the load lock modules 143, 144 are each constructed as a preliminary vacuum transfer chamber having an adjustable internal pressure. Moreover, the load lock modules 143, 144 each have a wafer mounting stage 153 or 154 for temporarily mounting a wafer W being transferred between the loader module 13 and the transfer module 138.

The transfer module 138 has disposed therein a frog leg-type transfer arm 155 that can bend/elongate and turn. The transfer arm 155 transfers the wafers W between the process modules 139 to 142 and the load lock modules 143, 144.

Each of the process modules 139 to 142 has a corresponding one of mounting stages 156 to 159 on which a wafer W to be processed is mounted. The process modules 139, 140 are each constructed like the first process module 25 in the substrate processing apparatus 10, the process module 141 is constructed like the second process module 34, and the process module 142 is constructed like the third process module 36 or 198. The wafers W can be subjected to etching in the process module 139 or 140, the COR processing in the process module 141, and the PHT processing in the process module 142.

In the substrate processing apparatus 137, a wafer W having a deposit film of a SiO₂ layer formed on side surfaces of a trench is transferred into the process module 141 and subjected to the COR processing, and then the wafer W is transferred into the process module 142 and subjected to the PHT processing.

It should be noted that operation of the component elements in the substrate processing apparatus 137 is controlled using a system controller constructed like the system controller 89 in the substrate processing apparatus 10. The number of process modules in the substrate processing apparatus 137 is not limited to four but may be six, for example.

What is claimed is:

1. A substrate processing apparatus for processing a substrate having a surface thereof formed with an oxide layer, comprising:
a chemical reaction processing apparatus adapted to cause a chemical reaction of the oxide layer with gas molecules to thereby produce a product on the surface of the substrate; and
a heat treatment apparatus adapted to heat the substrate on the surface of which the product has been produced,
wherein said heat treatment apparatus includes a generated gas analysis apparatus adapted to analyze gases generated from the heated substrate.

2. The substrate processing apparatus according to claim 1, wherein said heat treatment apparatus includes a housing chamber in which the substrate is housed and a gas exhaust system that exhausts gases in the housing chamber, and
said generated gas analysis apparatus is disposed in said gas exhaust system.

3. The substrate processing apparatus according to claim 2, wherein said generated gas analysis apparatus includes a gas introduction chamber into which the gases exhausted from said housing chamber are taken in, a plasma generation apparatus adapted to generate plasma in the gas introduction chamber, and a spectroscopic measurement apparatus adapted to spectrally disperse emissions from atoms or molecules in the gases excited by the plasma and measure dispersed light intensities.

4. The substrate processing apparatus according to claim 2, wherein said generated gas analysis apparatus includes an exhaust pipe through which the gases in the housing chamber are exhausted, a plasma generation apparatus adapted to generate plasma in the exhaust pipe, and a spectroscopic measurement apparatus adapted to spectrally disperse emissions from atoms or molecules in the gases excited by the plasma and measure dispersed light intensities.

5. The substrate processing apparatus according to claim 2, wherein said generated gas analysis apparatus includes an exhaust pipe through which the gases in the housing chamber are exhausted, a plasma generation apparatus adapted to generate plasma in the exhaust pipe, and a spectroscopic measurement apparatus adapted to spectrally disperse an afterglow observed downstream of a central part of plasma generation in the exhaust pipe and measure dispersed light intensities.

6. The substrate processing apparatus according to claim 2, wherein said generated gas analysis apparatus includes a mass analyzer.

7. The substrate processing apparatus according to claim 2, wherein said generated gas analysis apparatus includes a Fourier transform infrared spectrophotometer.

8. The substrate processing apparatus according to claim 1, wherein said heat treatment apparatus includes a housing chamber in which the substrate is housed, and said generated gas analysis apparatus is disposed in the housing chamber.

9. The substrate processing apparatus according to claim 8, wherein said generated gas analysis apparatus includes a gas introduction chamber into which the gases exhausted from said housing chamber is taken in, a plasma generation apparatus adapted to generate plasma in the gas introduction chamber, and a spectroscopic measurement apparatus adapted to spectrally disperse emissions from atoms or molecules in the gases excited by the plasma and measure dispersed light intensities.

10. The substrate processing apparatus according to claim 1, wherein the generated gas includes at least one of silicon tetrafluoride gas, ammonia gas, hydrogen fluoride gas, nitrogen gas, and hydrogen gas.

11. The substrate processing apparatus according to claim 1, wherein said chemical reaction processing apparatus includes a second housing chamber in which the substrate is housed, an ammonia gas supply system adapted to supply ammonia gas into the second housing chamber, a hydrogen fluoride gas supply system adapted to supply hydrogen fluoride gas into the second housing chamber, and a supplied gas analysis apparatus adapted to analyze at least one of the ammonia gas and the hydrogen fluoride gas supplied into the second housing chamber.

12. The substrate processing apparatus according to claim 1, wherein said chemical reaction processing apparatus includes a second housing chamber in which the substrate is housed, a hydrogen fluoride gas supply system adapted to supply hydrogen fluoride gas into the second housing chamber, and a supplied gas analysis apparatus adapted to analyze the hydrogen fluoride gas supplied to the second housing chamber.

13. The substrate processing apparatus according to claim 12, wherein said chemical reaction processing apparatus includes a supplied gas exhaust system adapted to exhaust the gas supplied into the second housing chamber, and
said supplied gas analysis apparatus is disposed in said supplied gas exhaust system.

14. The substrate processing apparatus according to claim 13, wherein said supplied gas analysis apparatus includes a second gas introduction chamber adapted to take in the gas exhausted from the second housing chamber, a second plasma generation apparatus adapted to generate plasma in said second gas introduction chamber, and a second spectroscopic measurement apparatus adapted to spectrally disperse emissions from atoms or molecules in the gases excited by the plasma and measure dispersed light intensities.

15. The substrate processing apparatus according to claim 13, wherein said supplied gas analysis apparatus includes a second exhaust pipe adapted to exhaust the gas in the second housing chamber, a second plasma generation apparatus adapted to generate plasma in the second exhaust pipe, and a second spectroscopic measurement apparatus adapted to spectrally disperse emissions from atoms or molecules in the gases excited by the plasma and measure dispersed light intensities.

16. The substrate processing apparatus according to claim 12, wherein said supplied gas analysis apparatus is disposed in the second housing chamber.

17. The substrate processing apparatus according to claim 16, wherein said supplied gas analysis apparatus includes a second gas introduction chamber adapted to take in the gases in the second housing chamber, a second plasma generation apparatus adapted to generate plasma in the second gas introduction chamber, and a second spectroscopic measurement apparatus adapted to spectrally disperse emissions from atoms or molecules in the gases excited by the plasma and measure intensities of dispersed light components.

18. A substrate processing termination detection method for use in a substrate processing apparatus for processing a substrate having a surface thereof formed with an oxide layer, comprising:
a chemical reaction processing step of causing a chemical reaction of the oxide layer with gas molecules to thereby produce a product on the surface of the substrate; and
a heat treatment step of heating the substrate on the surface of which the product has been produced,
wherein said heat treatment step includes a generated gas analysis step of analyzing gases generated from the heated substrate.

19. The termination detection method according to claim 18, wherein said generated gas analysis step includes a plasma generation step of generating a plasma for exciting atoms or molecules in the generated gases, and a spectroscopic measurement step of spectrally dispersing emissions from atoms or molecules in the gases excited by the plasma and measuring dispersed light intensities.

20. The termination detection method according to claim 18, wherein said generated gas analysis step includes a plasma generation step of generating a plasma for exciting atoms or molecules in the generated gases in an exhaust pipe through which the generated gases are exhausted, and a spectroscopic measurement step of spectrally dispersing emissions from atoms or molecules in the gases excited by the plasma and measuring dispersed light intensities.

21. The termination detection method according to claim 18, wherein said generated gas analysis step includes a plasma generation step of generating a plasma for exciting atoms or molecules in the generated gases in an exhaust pipe through which the generated gases are exhausted, and a spectroscopic measurement step of spectrally dispersing emissions from an afterglow observed downstream of a central part of plasma generation in the exhaust pipe and measuring dispersed light intensities.
